(19) United States
(12) Patent Application Publication
(10) Pub. No.: US 2020/0198962 A1
(43) Pub. Date: Jun. 25, 2020

(54) Device for Attaching Two Elements Such as a Chip, an Interposer and a Support

(71) Applicant: TRONIC'S MICROSYSTEMS, Crolles (FR)

(72) Inventors: Valérie Volant, Seyssinet Pariset (FR); Olivier Gigan, Grenoble (FR); Jacques Leclerc, Valence (FR)

(21) Appl. No.: 15/753,615

(22) PCT Filed: Sep. 6, 2016
(86) PCT No.: PCT/EP2016/070993

§ 371 Date: Feb. 20, 2018

(30) Foreign Application Priority Data
Sep. 29, 2015 (FR) 1559213

(51) Int. Cl. B81B 7/00; H01L 23/00

(52) U.S. Cl. CPC B81B 7/0048; H01L 24/32; H01L 2924/351; H01L 2224/32148; H01L 2924/1461; H01L 2224/32147

(57) ABSTRACT

A device for attaching two elements such as a chip, an interposer and a support, at least one of said two elements being micro-manufactured. The device includes at least one projecting stud structured in a first element extending facing the second element, the stud being configured to create an attachment area between one end of the stud and the second element. The device also includes an attachment layer deposited in the attachment area so as to attach the stud to the second element, and a recess made in the attachment area such that the attachment layer extends at least partially into the recess.

### TECHNICAL FIELD

The present disclosure concerns a device for attaching two elements in the microelectronics field such as a chip, an interposer and a support, at least one of said two elements being micro-manufactured. The disclosed embodiments make it possible to attach a micro-manufactured chip onto a support with or without an interposer. The disclosed embodiments are particularly advantageously applicable to sensors of the accelerometer or gyrometer type, pressure sensors, optical components or power components.

### BACKGROUND

Micro-manufactured chips comprise chips that are highly sensitive to external conditions, such as MEMS (micro-electromechanical system) chips or MOEMS (micro-opto-electromechanical system) chips. Micro-manufactured chips are sometimes sensitivity to thermomechanical stresses experienced by the support upon which the chip is mounted due to the difference in the thermal expansion coefficient between the silicon chip (TEC comprised between 2 and 4 ppm/° C.) and the alumina support (TEC comprised between 7 ppm/° C. and 12 ppm/° C.). This is more particularly the case for micro-manufactured chips the fine and sensitive mechanical structures thereof having, once assembled, localized or extended stress points that may disrupt the operation of the product.

To improve the sensitivity of micro-manufactured chips, it is necessary to limit the heat transfer or stress transfer or mechanical movements from the support to the chip.

These micro-manufactured chips are traditionally mounted on a support with or without an interposer between the chip and the support. The interposer serves to facilitate the mounting of the chip and/or to limit heat exchanges and mechanical stresses between the chip and the support.

U.S. patent application publication no. US 2008/251866 describes a chip connected to a support via an interposer. The interposer is mounted on the support by means of columns in such a way as to increase the thermal path between the interposer and the support. The heat exchanges are thus reduced between the chip, mounted on the interposer, and the support. However, this solution, by using both an interposer and columns, greatly increases the bulk of the mounting device between the chip and the support.

Furthermore, U.S. Pat. No. 8,901,681 describes a chip mounted directly on a support. The chip includes a projecting stud structured within the chip on the face across from the support in such a way as to create an attachment area between the stud and the support. An attachment layer, for example a glue, is then deposited between the stud and the support to attach the chip onto the support. The presence of the stud makes it possible to limit the contact area between the chip and the support, and thus to limit heat exchanges between the chip and the support. However, insofar as the surface of the stud in contact with the support is often insufficient, this solution does not allow the chip to be correctly attached to the support. Thus, in order to satisfy the attachment constraints, the surface of the stud in contact with the support is oversized.

The technical problem of the therefore consists in limiting the attachment surface between a chip and a support or an interposer while guaranteeing the quality of the attachment, while separating the attachment areas from the sensitive areas of the chip.

### SUMMARY OF THE DISCLOSURE

The present disclosure proposes to resolve this technical problem by using one or several studs having a recess such that the attachment layer extends at least partially into the recess.

To that end, the disclosure concerns a device for attaching two elements such as a chip, an interposer and a support, at least one of said two elements being micro-manufactured, the device comprising:
at least one projecting stud structured in a first element extending facing the second element,
the stud being configured to create an attachment area between one end of the stud and the second element,
an attachment layer deposited within the attachment area so as to attach the stud to the second element, and
a recess implemented at the attachment area such that the attachment layer extends at least partially into the recess.

The disclosed embodiments make it possible to precisely adjust the height of the attachment layer between the two elements, at least at the cavity, and thus to adjust a minimum mechanical stress between the two elements.

The improved mechanical strength between the two elements causes a reduction in the necessary attachment surface between the stud and the second element.

Furthermore, the attachment layer makes it possible to absorb part of the movement stresses between the chip and the support. Thus, the mechanical strength predetermined by the shape of the recess also makes it possible to adjust this mechanical absorption capacity of the movement stresses between the chip and the support.

According to one embodiment, the device further includes at least one micro-column formed by means of depositing material onto the stud or onto the opposite surface of the second element, the micro-column having a controlled height such as to guarantee, at the micro-column, a minimum thickness of the attachment layer. This embodiment has the advantage of guaranteeing the thickness of the attachment layer at least at the micro-columns, and thus of configuring a minimum mechanical strength between the two elements outside the area of the attachment layer penetrating the recess.

According to one embodiment, the recess is produced within the stud. This embodiment makes it possible to use a traditional second element without special treatment.

According to one embodiment, the recess is produced within the second element across from the stud, such that the stud can penetrate the recess. This embodiment makes it possible to guide the placement of the first element in relation to the second element, or vice versa.

According to one embodiment, the stud includes at least one longitudinal recess at the height of the recess, emerging at the end of the stud in contact with the attachment area.

This embodiment makes it possible to absorb some of the deformation stresses of the support. Indeed, the longitudinal recess creates an elasticity transverse to the attachment area such that the stud can deform, either under the effect of transverse stresses, or under the effect of axial stresses. Transverse stresses may appear between a chip and a support by means of differential expansion effects. Transverse stresses may appear between a chip and a support when the material of the attachment layer compresses, the longitudinal recess thus making it possible to obtain a shock absorbing effect.

According to one embodiment, the device includes a second stud structured within the second element, the second stud extending facing the stud of the first element in the attachment area. This embodiment makes it possible to adjust the height of the attachment area differently over the entire end surface of the stud.

According to one embodiment, the device includes a set of studs, with optionally different sizes and shapes, organized in an array. This embodiment makes it possible to improve the holding and the adhesion of the attachment area. The array also makes it possible to improve the dissipation of the stresses. The pattern of the array can be a square, a circle or any other shape. The array can be distributed uniformly over the entire surface of the chip or limited to a specific area.

According to one embodiment, the first element is a chip and the second element is a support, or vice versa. This embodiment makes it possible to do away with the interposer.

According to one embodiment, the device includes an interposer configured in such a way as to connect the chip and the support, the first element being the chip and the second element being the interposer, or vice versa.

### BRIEF DESCRIPTION OF THE FIGURES

The manner of implementing the embodiments disclosed herein, as well as the advantages deriving therefrom, will be clearly seen from the following embodiment, provided by way of non-limiting example, as a function of the appended figures wherein FIGS. 1 to 7 represent:

FIG. 1: a sectional view of a chip connected to a support by means of an interposer structured according to a first embodiment;

FIG. 2: a sectional view of the interposer of FIG. 1 according to a second embodiment;

FIG. 3: a sectional view of a structured chip connected directly to a support according to a third embodiment;

FIG. 4: a sectional view of a chip connected directly to a support structured according to a fourth embodiment;

FIG. 5: a sectional view of a chip connected directly to a support structured according to a fifth embodiment;

FIGS. 6a-6f: several bottom views of the arrangement of at least one stud in relation to the chip according to the various embodiments; and

FIGS. 7a-7d: several perspective front views of a stud according to the various embodiments.

### DETAILED DESCRIPTION

The disclosed embodiments make it possible to connect a chip and a support directly or by means of an interposer. When there is no interposer, the embodiments are implemented between the chip and the support. When there is an interposer, the embodiments can be implemented between the chip and the interposer, between the interposer and the support or both. To cover all of these embodiments, the description describes two elements 11, 12 between which the described embodiments are implemented. These elements 11, 12 are a chip, an interposer or a support. Amongst these elements 11, 12, the first element 11 is distinguished as being that which bears at least one stud 25.

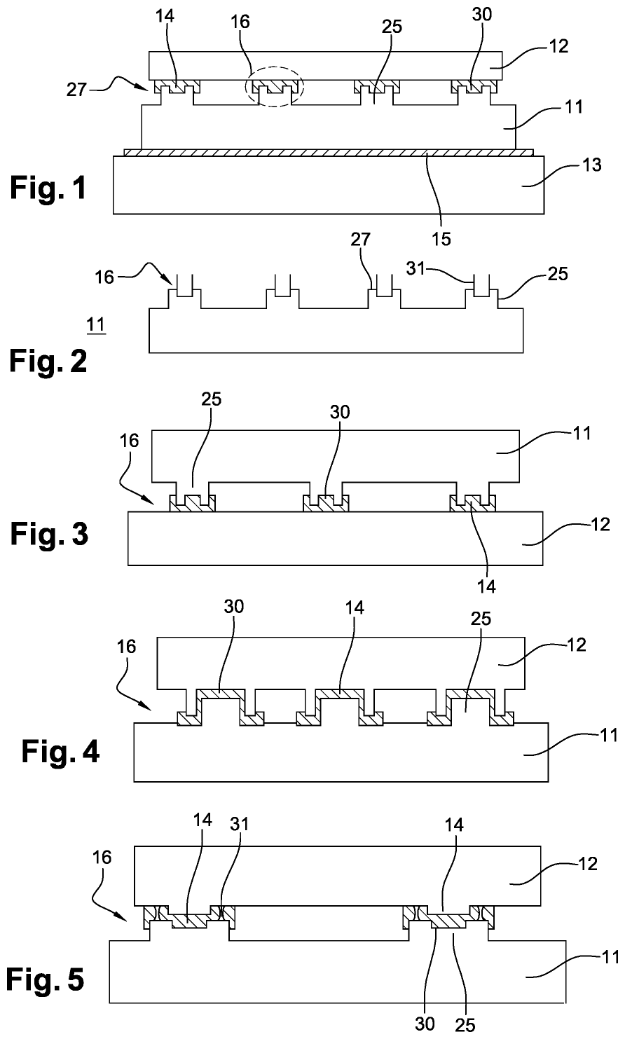

FIG. 1 illustrates a chip connected to a support by means of an interposer. The contemplated embodiments are implemented between two elements 11, 12, which are the chip and the interposer. The support then corresponds to a third element 13. A first element 11, the interposer, includes a lower face connected to the third element 13 by means of a traditional attachment layer 15. The upper face of the first element 11, opposite the lower face, is structured in such a way as to form four studs 25. The structuring operation consists in removing a thickness of material from the first element 11 in such a way as to create the studs 25 on the upper surface of the first element 11. Each stud 25 extends toward a second element 12, the chip. An upper end 27 of the stud 25 is configured in order to create an attachment area 16 with the second element 12 where an attachment layer 14 is deposited. In order to control the thickness of the attachment layer 14 between the two elements 11, 12, a recess 30 is made in the stud 25 and emerges at the upper end 27. Preferably, the recess 30 has a constant depth over the entire width thereof.

When the chip is applied to the attachment layer 14, the chip is pressed against the interposer such as to improve the adherence of the chip with the attachment layer 14. The attachment layer 14 can then overflow on either side of the stud 25, and it is particularly difficult to adjust the thickness of this attachment layer 14 outside the recess 30.

FIG. 2 illustrates a variation of FIG. 1 making it possible to address this problem using micro-columns 31 deposited on the upper end 27 of the studs 25 outside the recess 30. These micro-columns 31 make it possible to withstand the pressure of the chip against the interposer during the application of the chip. Preferably, the micro-columns 31 have a substantially equal height comprising of between 40 and 140 μm. Preferably, these micro-columns 31 are made from gold by welding a small bead of gold onto the interposer, then pulling this bead of gold such as to form a micro-column 31.

FIGS. 3 to 5 illustrate variation wherein the interposer is no longer necessary, the two elements 11, 12 being the chip and the support. In the case of FIG. 3, the first element 11 is the chip and the second element 12 is the support. The chip comprises three studs 25 extending toward the support wherein a recess 30 is arranged at the lower end. The attachment layer 14 is deposited between the lower end of the studs 25 and an upper face of the support.

In the case of FIG. 4, the first element 11 is the support and the second element 12 is the chip. The support includes three studs 25 extending toward the chip. The chip is also structured such as to create a recess 30 intended to come across from each stud 25 of the support. The recess 30 is therefore not formed in the stud 25, but in the second element 12. To that end, the shape of the recess 30 is adapted to the shape of the stud 25. To assemble the chip with the support, the attachment layer 14 can be positioned in the recess 30. The force of pressure on the chip then makes it possible to distribute the attachment layer 14 from the bottom of the recess 30 to the base of the stud 25.

Alternatively, the shape of the stud 25 and/or of the recess 30 can be frustoconical in such a way as to guide the positioning and the adjustment of the two elements 11-12 in relation to one another by centering the stud 25 in the recess 30.

In the case of FIG. 5, the first element 11 is still the support and the second element 12 is the chip. The recess 30 is structured at the upper end of each stud 25 and micro-columns are deposited on the upper end of the studs 25 outside the recess 30. Furthermore, the second element 12 is also structured in order to create a second stud extending toward the support within the attachment area 16. Preferably, the second stud has a surface adapted to the surface of the recess 30 such that the micro-columns are not in contact with the second stud. The second stud makes it possible to push the attachment layer 14 into the recess 30 during the placement of the chip on the support.

Preferably, the studs 25 are made during the collective manufacturing steps on a silicon wafer by a standard method for lithography and etching of the material at the end of the manufacturing process. The height of the studs 25 can be controlled and adjusted during the etching method by means of deep reactive ion etching. It is typically possible to make studs 25 wherein the height thereof comprises of between 10 μm and 300 μm. It is in particular the thickness of the substrate that limits the maximum height. For attachments using glue, a typical height from 40 μm to 80 μm is sufficient. Greater heights can improve the mechanical uncoupling functions depending on the topologies used, for example heights comprising of between 100 μm and 500 μm. The surface of the studs 25 can be made from silicon or covered by a dielectric (silicon oxide, nitride or the like), or by any types of metals in order to facilitate electrical contact or adhesion.

The manufacturing method does not induce any limitations regarding the type of shape of the stud 25. The patterns can be circles, squares, stars or any other shape. The patterns can be uniform, hollowed out, or have etching arrays. The definition of the attachment pattern directly on the rear face of the component during manufacturing allows for very simple self-alignment of the component during the final attachment onto the support, the attachment area being defined only on the first element 11. Thus, owing to the standard photolithography techniques on a silicon wafer, it is very easy to position the studs 25 precisely in relation to the moving inner parts of a chip, to within better than 5 μm. This is significantly better than the typical alignment during traditional attachments in assembling a chip and a support, which is about 50 μm.

The aim of the uncoupling between the chip and the support is to not transmit any external stresses to the inner moving parts except for the dimension to be measured. Among other things, all of the differential thermal stresses between the various materials will cause disruptive effects (drift, thermal hysteresis, offset, etc.). Ideally, the moving structure must therefore be completely suspended or the points of contact must be as small as possible.

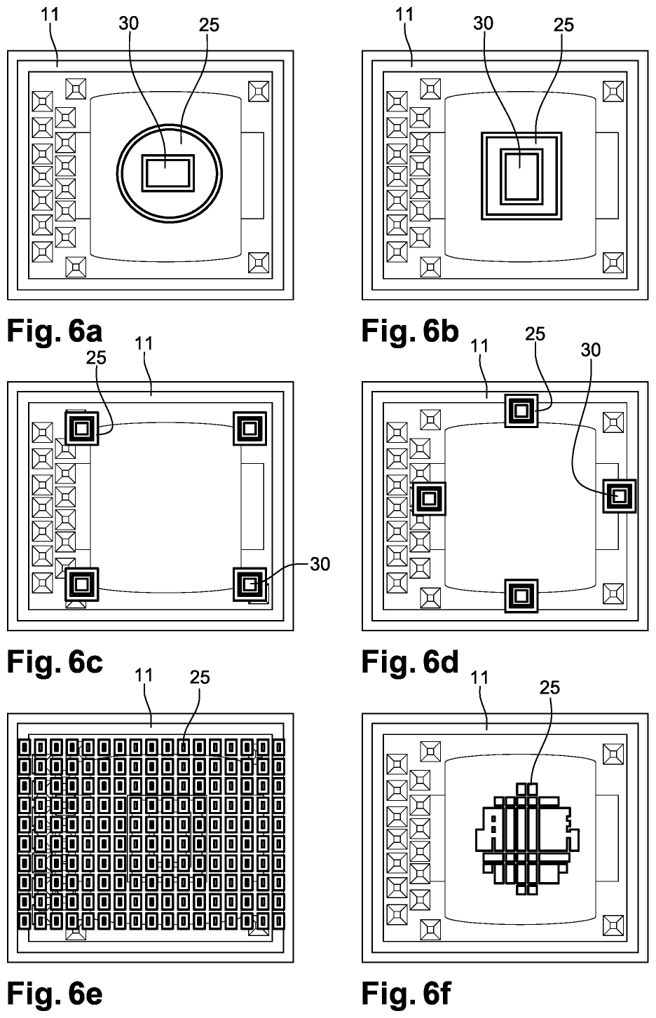

FIGS. 6a to 6a illustrate different shapes and topologies of the stud(s) 25 of a first element 11, for example a chip. FIGS. 6a and 6b illustrate a single stud 25, the section thereof being either oval or rectangular. FIGS. 6c and 6d illustrate four studs 25 positioned symmetrically such as to cooperate in order to absorb the movement stresses of the support in relation to the chip. FIGS. 6e and 6f illustrate sets of studs 25 organized in an array making it possible to improve the holding and adhesion of the attachment layer 14. Each set of studs 25 can also improve the dissipation of stresses. The array can be distributed uniformly over the entire surface, FIG. 6e, or limited to a specific area, FIG. 6f.

Alternatively, the geometry of the studs 25 of the array is adapted to the topology of the array in such a way as to adjust the uncoupling of the mechanical stresses between the first element 11 and the second element 12. For example, the second element 12 can be connected to the first element 11 by means of a central stud 25 and peripheral studs 25 with a deformation capacity of the peripheral studs 25 exceeding the deformation capacity of the central stud 25. It is thus possible to create variable mechanical uncoupling between the first element 11 and the second element 12 as a function of the position between the two elements 11-12. The deformation capacity of the stud 25 can be adjusted, for example, by means of a variation in the thickness of the stud 25 or an increase in the volume of the recess 30.

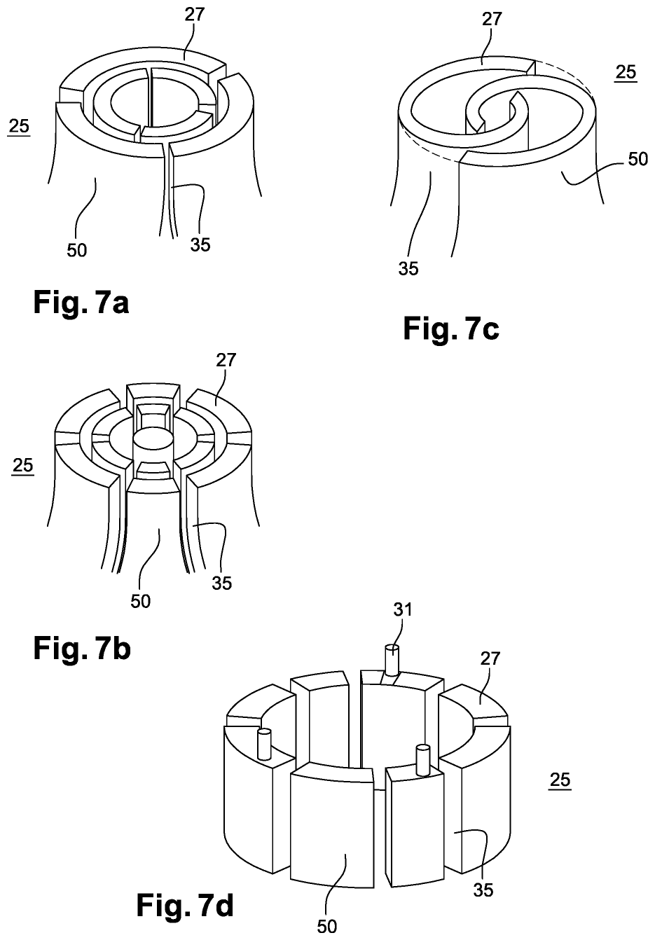

FIGS. 7a to 7e illustrate embodiments of the studs 25 wherein the studs 25 are hollow and have transverse elasticity. Thus, the studs 25 are able to deform, either under the effect of the transverse stresses relating to differential expansion effects, or under the effect of axial stresses that compress the attachment layer 14. To that end, each stud 25 has longitudinal recesses 35 allowing for deformation of the stud 25. Each recess 35 emerges at the end 27 of the stud 25 intended to come into the attachment area 16. The stud 25 is then sectioned into several strips 50 between the longitudinal recesses 35. In addition, in order to allowing twisting of the stud 25, the recesses 35 allow the attachment layer 14 to extend through the recesses 35 and to be distributed more easily between two elements 11, 12.

When the stud 25 is made in the form of strips 50, the recess 30 is defined by the inner volume between the strips 50. Each recess 35 is mathematically filled by a linear regression of two adjacent strips 50 such as to consider an inner wall of the stud 25 to be fictitiously continuous in order to define the recess 30.

The production of such a stud 25 is slightly more complex than that of a stud 25 without slits, but calls on the same type of method. By mechanical simulation of the system and stresses, it is possible to design complex geometries that tend to optimize this elastic effect and the reduction of the stresses.

For example, FIG. 7a illustrates a stud 25 including two concentric rings with different diameters, each ring being sectioned by three recesses 35. FIG. 7b illustrates a stud 25 including a central stud surrounded by two concentric rings with different diameters, each ring being sectioned by six recesses 35. FIG. 7c illustrates a stud 25 including two walls with a C-shaped section interlocked so as to form a recess 35 whose section between these walls is S-shaped. FIG. 7d illustrates a stud 25 including a ring sectioned by eight recesses 35 and the upper end 27 of which is provided with micro-columns 31.

Alternatively, the strips 50 can be independent of one another and positioned in different locations of the first element 11. In this case, the gluing is implemented by means of a joint positioned at the end 27 of the strips 50 or by completely filling the recess 30 included within the strips 50 when the slits are narrow enough.

Alternatively, the embodiments can be combined and moved in order to connect two different elements 11, 12. Alternatively, the studs 25 can also be positioned in order to guide the positioning of a chip on a support.

The embodiments described herein thus make it possible to increase the performance of a micro-manufactured chip by limiting the interaction thereof with the support thereof.

1. A device for attaching two elements such as a chip, an interposer and a support, at least one of said two elements being micro-manufactured, the device comprising:
at least one projecting stud structured in a first element extending facing the second element,
the stud being configured to create an attachment area between one end of the stud and the second element,
an attachment layer deposited in the attachment area so as to attach the stud to the second element, and
a recess made in the attachment area such that the attachment layer extends at least partially into the recess.

2. The device according to claim 1, further comprising at least one micro-column formed by depositing material onto the stud or onto the opposite surface of the second element, the micro-column having a controlled height such as to guarantee, at the micro-column, a minimum thickness of the attachment layer.

3. The device according to claim 1, wherein the recess is made in the stud.

4. The device according to claim 1, wherein the recess is made in the second element across from the stud, such that the stud can penetrate the recess.

5. The device according to claim 1, wherein the stud includes at least one longitudinal recess at the height of the recess, emerging at the end of the stud in contact with the attachment area.

6. The device according to claim 1, further comprising a second stud structured in the second element, the second stud extending facing the stud of the first element in the attachment area.

7. The device according to claim 1, further comprising a set of studs, optionally with different sizes and shapes, organized in an array.

8. The device according to claim 1, wherein the first element is a chip and the second element is a support, or vice versa.

9. The device according to claim 1, further comprising an interposer configured to connect the chip and the support, the first element being the chip and the second element being the interposer, or vice versa.
